(19) United States
(12) Patent Application Publication
(10) Pub. No.: US 2026/0096011 A1
(43) Pub. Date: Apr. 2, 2026

(54) VEHICLE CIRCUIT BOARD

(71) Applicants: AUTONETWORKS TECHNOLOGIES, LTD., Mie (JP); SUMITOMO WIRING SYSTEMS, LTD., Mie (JP); SUMITOMO ELECTRIC INDUSTRIES, LTD., Osaka (JP)

(72) Inventor: Makio NISHIZUKA, Osaka (JP)

(21) Appl. No.: 19/113,426

(22) PCT Filed: Aug. 21, 2023
(86) PCT No.: PCT/JP2023/029992

§ 371 Date: Mar. 20, 2025

(30) Foreign Application Priority Data
Sep. 22, 2022 (JP) 2022-151542

(51) Int. Cl. H05K 1/02; H05K 1/11; H05K 5/00

(52) U.S. Cl. CPC H05K 1/0206; H05K 1/115; H05K 5/0026; H05K 2201/09227; H05K 2201/10522; H05K 2201/10545; H05K 2201/10628; H05K 2201/10757

(57) ABSTRACT

It is aimed to provide a vehicle circuit board capable of enhancing heat dissipation. A circuit board (10) to be installed in a vehicle includes a board (20), a first electronic component (30) to be mounted on the board (20) and including a heat source terminal (33), a second electronic component (40) to be mounted on the board (20) and having at least any one of a communication function, a memory function and an information processing function, and a heat transfer path (50) provided on the board (20) to connect the heat source terminal (33) and an empty terminal (43) of the second electronic component (40).

### TECHNICAL FIELD

The present disclosure relates to a vehicle circuit board.

### BACKGROUND

Conventionally, various methods have been known as measures against heat of a circuit board installed in a vehicle. For example, a method for connecting a lead portion of a heat generating component mounted on a circuit board and a fixing peg of a connector mounted on the circuit board via a printed wiring is described in Patent Document 1 below. According to this method, heat of the heat generating component is allowed to escape to the fixing peg of the connector along the printed wiring. By utilizing the fixing peg as a part of a heat dissipation structure, heat dissipation can be enhanced without using a component dedicated for measures against heat.

### PRIOR ART DOCUMENT

### Patent Document

Patent Document 1: JP 2017-041485 A

### SUMMARY OF THE INVENTION

### Problems to be Solved

In the configuration as described above, a heat dissipation destination of the heat generating component is limited to the fixing peg. There is a demand to enhance the heat dissipation of a vehicle circuit board by increasing heat dissipation destinations of the heat generating component.

The present disclosure was completed on the basis of the above situation and aims to provide a vehicle circuit board capable of enhancing heat dissipation.

### Means to Solve the Problem

The present disclosure is directed to a vehicle circuit board to be installed in a vehicle, the vehicle circuit board being provided with a board, a first electronic component to be mounted on the board, the first electronic component including a heat source terminal, a second electronic component to be mounted on the board, the second electronic component having at least any one of a communication function, a memory function and an information processing function, and a heat transfer path provided on the board to connect the heat source terminal and an empty terminal of the second electronic component.

### Effect of the Invention

According to the present disclosure, it is possible to provide a vehicle circuit board capable of enhancing heat dissipation.

### BRIEF DESCRIPTION OF THE DRAWINGS

FIG. 1 is a plan view showing a vehicle circuit board according to an embodiment.

FIG. 2 is a section showing the vehicle circuit board, corresponding to a cross-section along A-A of FIG. 1.

FIG. 3 is a section showing the vehicle circuit board, corresponding to a cross-section along B-B of FIG. 1.

FIG. 4 is a section showing the vehicle circuit board, corresponding to a cross-section along C-C of FIG. 1.

### DETAILED DESCRIPTION TO EXECUTE THE INVENTION

### Description of Embodiments of Present Disclosure

First, embodiments of the present disclosure are listed and described.

The vehicle circuit board of the present disclosure is as follows.

(1) The vehicle circuit board of the present disclosure is to be installed in a vehicle and provided with a board, a first electronic component to be mounted on the board, the first electronic component including a heat source terminal, a second electronic component to be mounted on the board, the second electronic component having at least any one of a communication function, a memory function and an information processing function, and a heat transfer path provided on the board to connect the heat source terminal and an empty terminal of the second electronic component. According to this configuration, heat of the first electronic component is allowed to escape to the empty terminal of the second electronic component via the heat transfer path. Since the empty terminal of the second electronic component can be used as a heat dissipation structure, heat dissipation can be enhanced.

(2) The first and second electronic components may be both arranged on a first surface, the first surface being one of both surfaces of the board, and the heat transfer path may extend from the heat source terminal to the empty terminal of the second electronic component on the first surface. According to this configuration, the heat of the first electronic component is allowed to escape to the empty terminal of the second electronic component via the heat transfer path on the first surface. Since the empty terminal of the second electronic component can be used as the heat dissipation structure, heat dissipation can be enhanced.

(3) The board may be a laminated board obtained by laminating a plurality of insulation layers, the first and second electronic components may be both arranged on a first surface, the first surface being one of both surfaces of the laminated board, and the heat transfer path may extend from the heat source terminal to the empty terminal of the second electronic component through inside of the laminated board. According to this configuration, the heat of the first electronic component is allowed to escape to the empty terminal of the second electronic component through the inside of the laminated board. Even if the heat transfer path cannot be arranged on the first surface, heat dissipation can be enhanced since the empty terminal of the second electronic component can be used as the heat dissipation structure.

(4) The first electronic component may be arranged on a first surface, the first surface being one of both surfaces of the board, and the second electronic component is arranged on a second surface, the second surface being the other of the both surfaces of the board, and the heat transfer path may extend from the heat source terminal to the empty terminal of the second electronic component through the board in a thickness direction. According to this configuration, the heat of the first electronic component is allowed to escape to the empty terminal of the second electronic component through the board in the thickness direction. Since the empty terminal of the second electronic component arranged on the second surface can be used as the heat dissipation structure, heat dissipation can be enhanced.

(5) The empty terminal may be a terminal for input/output having a communication function. According to this configuration, since the terminal for input/output can be used as the heat dissipation structure, heat dissipation can be enhanced.

(6) The empty terminal may be a terminal for information storage. According to this configuration, since the terminal for information storage can be used as the heat dissipation structure, heat dissipation can be further enhanced.

(7) A maximum value of a current to be input to the first electronic component may be larger than a maximum value of a current to be input to the second electronic component. According to this configuration, the first electronic component is a high heat generating component and the second electronic component is a component with lower heat generation than the first electronic component.

(8) The first electronic component may be a power device. According to this configuration, heat of the power device can be allowed to escape to the empty terminal of the second electronic component.

### Details of Embodiment of Present Disclosure

A specific example of a vehicle circuit board of the present disclosure is described below with reference to the drawings. Note that the present invention is not limited to these illustrations, but is represented by claims and intended to include all changes in the scope of claims and in the meaning and scope of equivalents.

The vehicle circuit board (hereinafter, referred to as a circuit board 10) of this embodiment is installed in a vehicle such as an electric vehicle or a hybrid vehicle. The circuit board 10 is provided in an ECU (Electronic Control Unit).

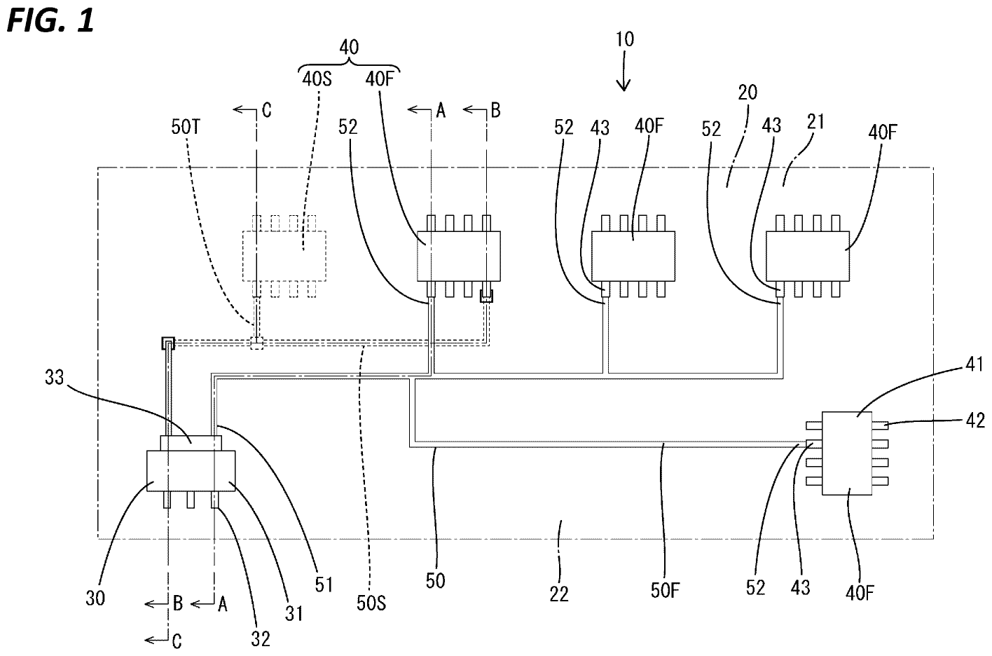

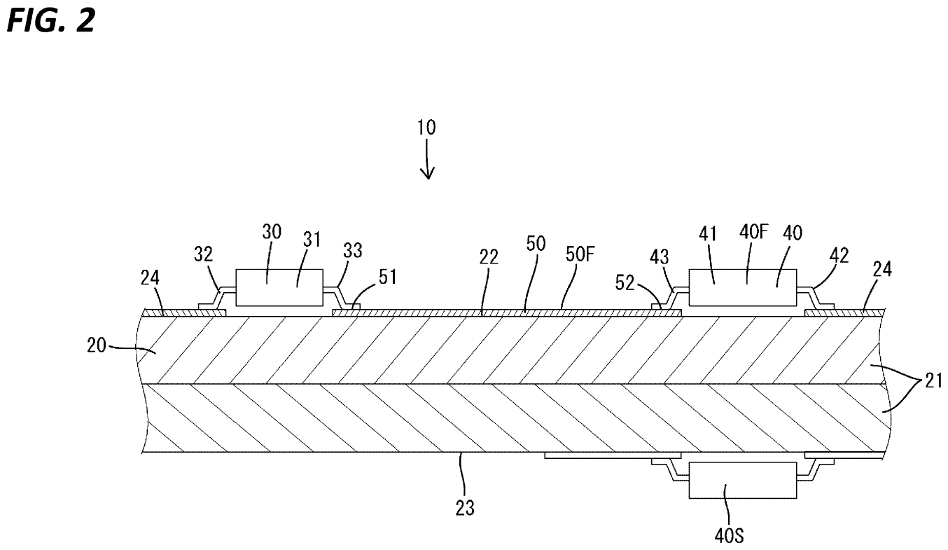

As shown in FIG. 1, the circuit board 10 is provided with a board 20, a first electronic component 30, second electronic components 40 and a heat transfer path 50. As shown in FIG. 2, the board 20 is a laminated board obtained by laminating two insulation layers 21. Wiring patterns 24 are formed on the board 20. The wiring patterns 24 are formed on a first surface 22, which is one of both surfaces of the board 20, and a second surface 23, which is the other of the both surfaces of the board 20 and inside the board 20. The wiring patterns 24 contain an electrically conductive material such as copper foils. The wiring patterns 24 are omitted as appropriate in figures.

The first and second electronic components 30, 40 are mounted on the board 20. The first and second electronic components 30, 40 generate heat by being energized. A heat generation amount of the first electronic component 30 is larger than those of the second electronic components 40. The first electronic component 30 is a high heat generating component, and the second electronic components 40 are low heat generating components. A maximum value of a current to be input to the first electronic component 30 is larger than those of currents to be input to the second electronic components 40.

The first electronic component 30 is mounted on the first surface 22. The first electronic component 30 is a power device. Power output from the first electronic component 30 and the heat generation amount of the first electronic component 30 are relatively large and a heat resistant temperature is also relatively high.

As shown in FIG. 2, the first electronic component 30 includes a body 31, terminals 32 and a heat source terminal 33. The body 31 includes a box-shaped package. The package is made of plastic, metal, ceramic or the like. A plurality of the terminals 32 project from the bottom and side surfaces of the body 31. The terminal 32 is a lead, an electrode pad or the like. The heat source terminal 33 is a member made of metal and exposed on the outer surface of the body 31. The heat source terminal 33 is a heat dissipation pad, a GND terminal, a heat sink or the like. A heat generation amount of the heat source terminal 33 is larger than that of the terminal 32. A volume of a part of the heat source terminal 33 exposed from the body 31 is larger than that of a part of each terminal 32 exposed from the body 31.

The type of the package of the first electronic component 30 may be of a TO (Transistor Outline) type, an SOT (Small Outline Transistor) type, a QFP (Quad Flat Package) type, a QFN (Quad Flat Non-leaded Package) type, a BGA (Ball Grid Array) type or the like. The first electronic component 30 may be configured as an SoC (System on a Chip). The first electronic component 30 may be an LDO (Low Drop Output) linear regulator.

A plurality of the second electronic components 40 are provided on the board 20. The second electronic components 40 include first surface components 40F mounted on the first surface 22 and a second surface component 40S mounted on the second surface 23. The second electronic component 40 has at least any one of a communication function, a memory function and an information processing function. The second electronic component 40 conducts data communication with outside, stores information or processes various pieces of data. The second electronic component 40 may be a microcomputer, a memory or the like. A heat generation amount of the second electronic component 40 is relatively small.

The second electronic component 40 includes a body 41, terminals 42 and an empty terminal 43. The body 41 includes a box-shaped package. The package may be made of plastic, metal, ceramic or the like. The terminals 42 project from the bottom and side surfaces of the body 41. The terminal 42 may be a lead, an electrode pad or the like.

The empty terminal 43 is any one of the terminals 42 of the second electronic component 40. Which of the terminals 42 of the second electronic component 40 is set as the empty terminal 43 may be freely determined. The empty terminal 43 of the second electronic component 40 does not transfer information and power to and from outside. The empty terminal 43 of the second electronic component 40 is not connected to the wiring pattern 24. Even if heat flows in the empty terminal 43 of the second electronic component 40, that heat does not affect the functions of the second electronic component 40. The empty terminal 43 of the second electronic component 40 may be provided only to work as the package. The empty terminal 43 of the second electronic component 40 may be provided only for future functional enhancement of the second electronic component 40. For example, the empty terminal 43 may be an auxiliary terminal for common mode (noise suppression) control. For example, the empty terminal 43 may be a terminal for input/output or a terminal for information storage.

The type of the package of the second electronic component 40 may be of an SOP (Small Outline Package) type, an SON type (Small Outline Non-leaded Package) type, a QFP (Quad Flat Package) type, a QFN (Quad Flat Non-leaded Package) type, a BGA (Ball Grid Array) type or the like.

The heat transfer path 50 is provided on the board 20. The heat transfer path 50 connects the heat source terminal 33 of the first electronic component 30 and the empty terminals 43 of the second electronic components 40. The heat transfer path 50 is made of a heat transfer material high in thermal conductivity. The heat transfer path 50 may be made of an electrically conductive material such as a copper foil, similarly to the wiring patterns 24. The heat transfer path 50 is neither separated from nor crossing the wiring patterns 24. A width (dimension orthogonal to an extension direction) of the heat transfer path 50 is 0.5 mm or more. If the width of the heat transfer path 50 is too small, a heat dissipation effect may be reduced. However, since the width of the heat transfer path 50 is 0.5 mm or more, a sufficient heat dissipation effect can be obtained.

As shown in FIG. 2, the heat transfer path 50 includes a first heat transfer path 50F extending from the heat source terminal 33 of the first electronic component 30 to the first surface components 40F. The first heat transfer path 50F extends from a first pad 51 to second pads 52. The heat source terminal 33 of the first electronic component 30 is soldered to the first pad 51. The empty terminal 43 of the second electronic component 40 is soldered to the second pad 52. The first heat transfer path 50F is in close contact with the first surface 22. As shown in FIG. 1, the first heat transfer path 50F includes one first pad 51 and a plurality of second pads 52. The first heat transfer path 50F is branched from the first pad 51 toward the respective second pads 52. Each second pad 52 is provided at the position of the empty terminal 43 of each second electronic component 40.

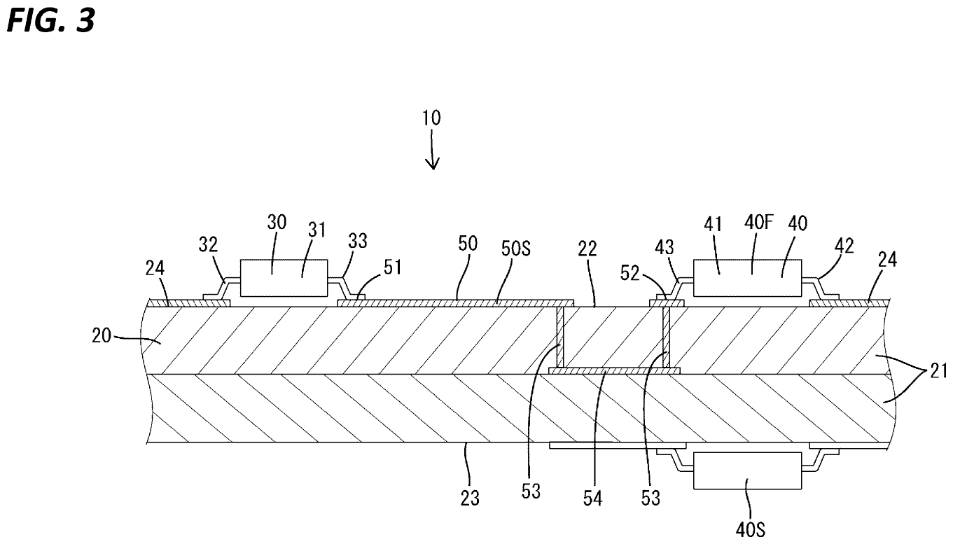

The heat transfer path 50 includes a second heat transfer path 50S extending from the heat source terminal 33 of the first electronic component 30 to the first surface components 40F through the inside of the board 20 as shown in FIG. 3. The second heat transfer path 50S includes vias 53 and an inner layer 54. The second heat transfer path 50S extends from the first pad 51 along the first surface 22. The vias 53 penetrate through the insulation layer 21 from the first surface 22 to the inner layer 54 in a thickness direction. The vias 53 connect the second heat transfer path 50S on the first surface 22 and the inner layer 54. The inner layer 54 is arranged between the laminated insulation layers 21.

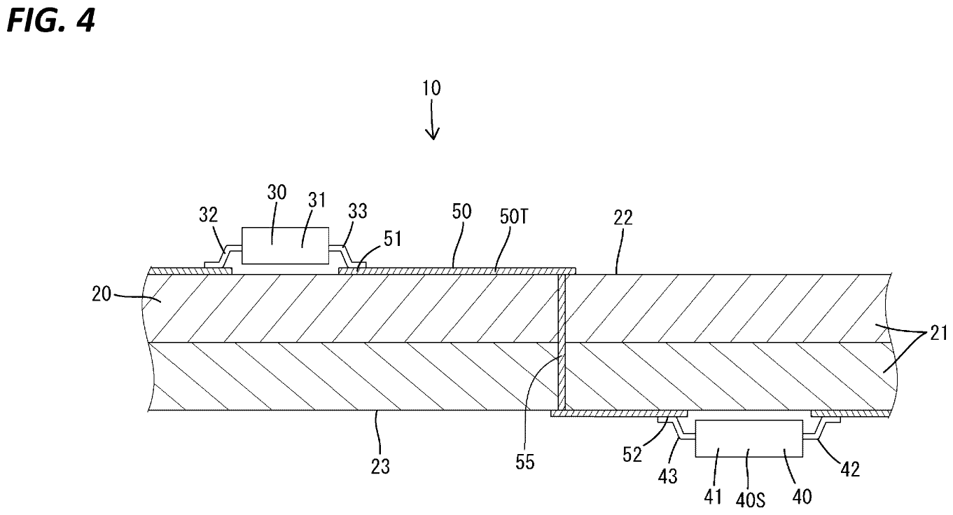

The heat transfer path 50 includes a third heat transfer path 50T extending from the heat source terminal 33 of the first electronic component 30 to the second surface component 40S as shown in FIG. 4. The third heat transfer path 50T includes a via 55. The third heat transfer path 50T extends from the first pad 51 along the first surface 22. The via 55 penetrates through the board 20 from the first surface 22 to the second surface 23 in the thickness direction. The via 55 connects the third heat transfer path 50T on the first surface 22 and the third heat transfer path 50T on the second surface 23. The third heat transfer path 50T extends from the via 55 to the second pad 52 along the second surface 23.

Next, functions and effects of the embodiment configured as described above are described. The circuit board 10 is installed in the vehicle. The circuit board 10 is provided with the board 20, the first electronic component 30, the second electronic components 40 and the heat transfer path 50. The first electronic component 30 is mounted on the board 20 and includes the heat source terminal 33. The second electronic component 40 is mounted on the board 20 and has at least any one of the communication function, the memory function and the information processing function. The heat transfer path 50 is provided on the board 20 and connects the heat source terminal 33 and the empty terminals 43 of the second electronic components 40. According to this configuration, heat of the first electronic component 30 is allowed to escape to the empty terminals 43 of the second electronic components 40 via the heat transfer path 50. Since the empty terminals 43 of the second electronic components 40 can be used as a heat dissipation structure, heat dissipation can be enhanced.

The plurality of second electronic components 40 are provided around the first electronic component 30. According to this configuration, by providing the plurality of second electronic components 40, a plurality of heat dissipation destinations can be ensured and the temperature of the first electronic component 30 can be efficiently reduced. The number of the arranged second electronic components 40 is considerably more than connector fixing pegs and unused terminals also in one ECU. Thus, the empty terminals 43 of the multitude of second electronic components 40 can be easily ensured as the heat dissipation destinations for the heat of the first electronic component 30, wherefore heat dissipation can be enhanced. Further, since gel or the like needs not be used as a heat dissipation structure and the use of a high heat generating component for the heat dissipation of the circuit board 10 and the like need not be refrained, the circuit board 10 can be reduced in cost and size.

Any of the first and second electronic components 30, 40 is arranged on the first surface 22 of the board 20. The first heat transfer path 50F extends from the heat source terminal 33 to the empty terminals 43 of the second electronic components 40 on the first surface 22. According to this configuration, the heat of the first electronic component 30 is allowed to escape to the empty terminals 43 of the second electronic components 40 via the heat transfer path 50 on the first surface 22. Since the empty terminals 43 of the second electronic components 40 can be used as the heat dissipation structure, heat dissipation can be enhanced.

The board 20 is the laminated board obtained by laminated the two insulation layers 21. Any of the first and second electronic components 30, 40 is arranged on the first surface 22 of the board 20. The second heat transfer path 50S extends from the heat source terminal 33 to the empty terminals 43 of the second electronic components 40 through the inside of the board 20. According to this configuration, the heat of the first electronic component 30 is allowed to escape to the empty terminals 43 of the second electronic components 40 through the inside of the board 20. Even if the first heat transfer path 50F cannot be arranged on the first surface 22, heat dissipation can be enhanced since the empty terminals 43 of the second electronic components 40 can be used as the heat dissipation structure.

The first electronic component 30 is arranged on the first surface 22 of the board 20. The second electronic component 40 is arranged on the second surface 23 of the board 20. The third heat transfer path 50T extends from the heat source terminal 33 to the empty terminal 43 of the second electronic component 40 through the board 20 in the thickness direction. According to this configuration, the heat of the first electronic component 30 is allowed to escape to the empty terminal 43 of the second electronic component 40 through the board 20 in the thickness direction. Since the empty terminal 43 of the second electronic component 40 arranged on the second surface 23 can be used as the heat dissipation structure, heat dissipation can be enhanced.

The empty terminal 43 is the terminal for input/output having a communication function. According to this configuration, since the terminal 42 for input/output can be used as the heat dissipation structure, heat dissipation can be further enhanced.

The empty terminal 43 is the terminal for information storage. According to this configuration, since the terminal 42 for information storage can be used as the heat dissipation structure, heat dissipation can be further enhanced.

A maximum value of a current to be input to the first electronic component 30 is larger than those of currents to be input to the second electronic components 40. According to this configuration, the first electronic component 30 is a high heat generating component and the second electronic components 40 are components with lower heat generations than the first electronic component 30.

The first electronic component 30 is a power device. According to this configuration, heat of the power device can be allowed to escape to the empty terminals 43 of the second electronic components 40.

### Other Embodiments of Present Disclosure

The embodiment disclosed this time should be considered illustrative in all aspects, rather than restrictive.

Although the board 20 is the laminated board including the two insulation layers in the case of the above embodiment, a board may be composed of only one layer or may be a laminated board including three or more insulation layers.

Although the heat transfer path 50 includes the first heat transfer path 50F, the second heat transfer path 50S and the third heat transfer path 50T in the case of the above embodiment, a heat transfer path may include only any one of first, second and third heat transfer paths.

Although the numbers and arrangement of the first and second electronic components 30, 40 are illustrated in the above embodiment, these may be changed.

### LIST OF REFERENCE NUMERALS

10 . . . circuit board (vehicle circuit board)
20 . . . board
21 . . . insulation layer
22 . . . first surface
23 . . . second surface
24 . . . wiring pattern
30 . . . first electronic component
31 . . . body
32 . . . terminal
33 . . . heat source terminal
40 . . . second electronic component
40F . . . first surface component
40S . . . second surface component
41 . . . body
42 . . . terminal
43 . . . empty terminal
50 . . . heat transfer path
50F . . . first heat transfer path
50S . . . second heat transfer path
50T . . . third heat transfer path
51 . . . first pad
52 . . . second pad
53 . . . via
54 . . . inner layer
55 . . . via

1. A vehicle circuit board to be installed in a vehicle, comprising:
a board;
a first electronic component to be mounted on the board, the first electronic component including a heat source terminal;
a second electronic component to be mounted on the board, the second electronic component having at least any one of a communication function, a memory function and an information processing function, the second electronic component including a body having a box-shaped package and a terminal and an empty terminal projecting from the body; and
a heat transfer path provided on the board to connect the heat source terminal and the empty terminal of the second electronic component.

2. The vehicle circuit board of claim 1, wherein:
the first and second electronic components are both arranged on a first surface, the first surface being one of both surfaces of the board, and
the heat transfer path extends from the heat source terminal to the empty terminal of the second electronic component on the first surface.

3. The vehicle circuit board of claim 1, wherein:
the board is a laminated board obtained by laminating a plurality of insulation layers,
the first and second electronic components are both arranged on a first surface, the first surface being one of both surfaces of the laminated board, and
the heat transfer path extends from the heat source terminal to the empty terminal of the second electronic component through inside of the laminated board.

4. The vehicle circuit board of claim 1, wherein:
the first electronic component is arranged on a first surface, the first surface being one of both surfaces of the board, and the second electronic component is arranged on a second surface, the second surface being the other of the both surfaces of the board, and
the heat transfer path extends from the heat source terminal to the empty terminal of the second electronic component through the board in a thickness direction.

5. The vehicle circuit board of claim 1, wherein the empty terminal is the empty terminal of the second electronic component including a terminal for input/output having a communication function.

6. The vehicle circuit board of claim 1, wherein the empty terminal is the empty terminal of the second electronic component including a terminal for information storage.

7. The vehicle circuit board of claim 1, wherein a maximum value of a current to be input to the first electronic component is larger than a maximum value of a current to be input to the second electronic component.

8. The vehicle circuit board of claim 1, wherein the first electronic component is a power device.
